(19) United States
(12) Patent Application Publication
(10) Pub. No.: US 2014/0338955 A1
(43) Pub. Date: Nov. 20, 2014

(54) PRINTED CIRCUIT BOARD

(71) Applicant: SAMSUNG ELECTRO-MECHANICS CO., LTD., Suwon (KR)

(72) Inventors: Mi Jin Park, Suwon (KR); Jeong Ho Lee, Suwon (KR); Young Nam Hwang, Suwon (KR); Young Do Kweon, Suwon (KR)

(73) Assignee: SAMSUNG ELECTRO-MECHANICS CO., LTD., Suwon (KR)

(21) Appl. No.: 14/094,349

(22) Filed: Dec. 2, 2013

(30) Foreign Application Priority Data
May 14, 2013 (KR) 10-2013-0054411

(51) Int. Cl. H05K 1/02

(52) U.S. Cl. CPC H05K 1/0298
USPC 174/250

(57) ABSTRACT

Disclosed herein is a printed circuit board. According to a preferred embodiment of the present invention, the printed circuit board, includes: a base board; an upper build-up layer which is formed on the base board and includes an upper insulating layer and an upper circuit layer having at least one layer; and a lower build-up layer which is formed beneath the base board, has a different thickness from the upper build-up layer, and includes a lower insulating layer and a lower circuit layer having at least one layer.

### CROSS REFERENCE TO RELATED APPLICATION

This application claims the benefit of Korean Patent Application No. 10-2013-0054411, filed on May 14, 2013, entitled “Printed Circuit Board” which is hereby incorporated by reference in its entirety into this application.

### BACKGROUND OF THE INVENTION

1. Technical Field

The present invention relates to a printed circuit board.

2. Description of the Related Art

In general, a printed circuit board is implemented by wiring a copper foil or copper foils on one surface or both surfaces of a board made of various kinds of thermosetting synthetic resins, fixedly disposing integrated circuits (ICs) or electronic components on the board, and implementing electrical wirings therebetween and then coating the electrical wirings with an insulator.

With the recent development of electronic industries, a demand for multi-functional and light and small electronic components has rapidly increased. Therefore, there is a need to increase wiring density of a printed circuit board on which the electronic components are mounted and reduce a thickness thereof.

In particular, in a general build-up wiring board, a build-up layer is formed on a core board (US Patent Laid-Open Publication No. 2002-0182958). Warpage of the printed circuit board may occur due to the build-up layers formed on and beneath the printed circuit board.

### SUMMARY OF THE INVENTION

The present invention has been made in an effort to provide a printed circuit board with reduced warpage.

According to a preferred embodiment of the present invention, there is provided a printed circuit board, including: a base board; an upper build-up layer which is formed on the base board and includes an upper insulating layer and an upper circuit layer of at least one layer; and a lower build-up layer which is formed beneath the base board, has a different thickness from the upper build-up layer, and includes a lower insulating layer and a lower circuit layer of at least one layer.

The thickness of the upper build-up layer may be thicker than that of the lower build-up layer.

The thickness of the upper build-up layer may be thinner than that of the lower build-up layer.

A total thickness of the upper insulating layer may be thicker than that of the lower insulating layer.

A total thickness of the upper insulating layer may be thinner than that of the lower insulating layer.

A total thickness of the upper circuit layer may be thicker than that of the lower circuit layer.

A total thickness of the upper circuit layer may be thinner than that of the lower circuit layer.

A layer number of the upper insulating layer and the upper circuit layer may be larger than that of the lower insulating layer and the lower circuit layer.

A layer number of the upper insulating layer and the upper circuit layer may be smaller than that of the lower insulating layer and the lower circuit layer.

A ratio of the thickness of the upper build-up layer and the thickness of the lower build-up layer may be 20% or less.

A ratio of a total thickness of the upper circuit layer and a total thickness of the lower circuit layer may be 20% or less.

A ratio of a total thickness of the upper circuit layer and a total thickness of the lower circuit layer may be 20% or less.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplified diagram illustrating a printed circuit board according to a preferred embodiment of the present invention;

FIG. 2 is an exemplified diagram illustrating a printed circuit board according to another preferred embodiment of the present invention;

FIG. 3 is an exemplified diagram illustrating an analysis result of warpage according to the preferred embodiment of the present invention; and

FIG. 4 is an exemplified diagram illustrating an analysis result of warpage according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

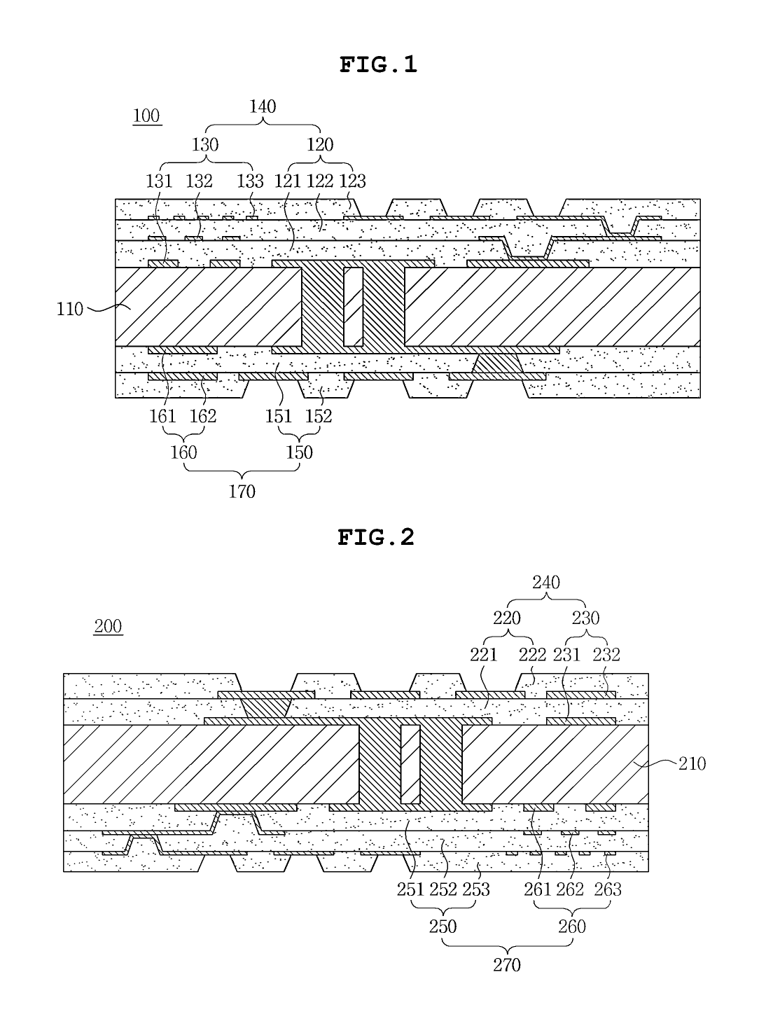

FIG. 1 is an exemplified diagram illustrating a printed circuit board according to a preferred embodiment of the present invention.

Referring to FIG. 1, a printed circuit board 100 may include a base board 110, an upper build-up layer 140, and a lower build-up layer 170.

The printed circuit board 100 according to the preferred embodiment of the present invention may be an asymmetrical board in which thicknesses of the upper build-up layer 140 and the lower build-up layer 170 formed on one side and the other side thereof are different from each other.

The base board 110 may be an insulating board, a printed circuit board, a ceramic board, and a metal board having an anodizing layer. Generally, the insulating board may be made of a composite polymer resin used as an inter-layer insulating material. The insulating board may be made of at least one of prepreg, Ajinomoto build-up film (ABF), FR-4, and bismaleimide triazine (BT).

In the printed circuit board an internal circuit of at least one layer may be formed on an insulating layer. In this case, the insulating layer may be a composite polymer resin generally used as an inter-layer insulating material. The internal circuit may be made of conductive materials generally used at the time of forming a circuit.

The ceramic board may be made of metal-based nitride or a ceramic material. The ceramic board may include aluminum nitride (AlN) or silicon nitride (SiN) that is the metal-based nitride. The ceramic board may include aluminum oxide (Al₂O₃) or beryllium oxide (BeO) that is the ceramic material. However, the material of the ceramic board is not particularly limited thereto.

The metal board may be made of metal materials that may be easily available at relatively low cost and aluminum (Al) or aluminum alloy having excellent heat transfer characteristics. Further, the anodizing layer may be formed by dipping the metal board made of aluminum or aluminum alloy into electrolytes, such as boric acid, phosphoric acid, sulfuric acid, chromic acid, and the like, and then applying an anode to the metal board and a cathode to the electrolyte. The so formed anodizing layer may be an aluminum anodizing layer (Al₂O₃). The anodizing layer may have insulation and high heat transfer characteristics.

The upper build-up layer 140 is formed on one side of the base board 110. The upper build-up layer 140 may include the upper insulating layer 120 having at least one layer. Further, the upper build-up layer 140 may include an upper circuit layer 130 having at least one layer. According to the preferred embodiment of the present invention, the upper build-up layer 140 may include the upper insulating layer 120 of three layers. For example, the upper insulating layer 120 may include a first upper insulating layer 121, a second upper insulating layer 122, and a third upper insulating layer 123. Further, the upper build-up layer 140 may include the upper circuit layer 130 having three layers. For example, the upper circuit layer 130 may include a first upper circuit layer 131, a second upper circuit layer 132, and a third upper circuit layer 133.

The lower build-up layer 170 is formed on the other side of the base board 110. The lower build-up layer 170 may be formed to be thinner than the upper build-up layer 140. The lower build-up layer 170 may include a lower insulating layer 150 having at least one layer. Further, the lower build-up layer 170 may include a lower circuit layer 160 having at least one layer. According to the preferred embodiment of the present invention, the lower build-up layer 170 may include the lower insulating layer 150 having two layers. For example, the lower insulating layer 150 may include a first lower insulating layer 151 and a second lower insulating layer 152. Further, the lower build-up layer 170 may include the lower circuit layer 160 having two layers. The lower circuit layer 160 may include a first lower circuit layer 161 and a second lower circuit layer 162.

The upper insulating layer 120 and the lower insulating layer 150 may be a composite polymer resin used as an inter-layer insulating material. For example, the upper insulating layer 120 and the lower insulating layer 150 may be made of a thermosetting resin, such as epoxy resin, and the like. The epoxy resin may an Ajinomoto build up film (ABF), FR-4, bismaleimide triazine (BT), and the like. Further, the upper insulating layer 120 and the lower insulating layer 150 may be made of a thermoplastic resin. The thermoplastic resin may be polyimide. Further, the upper insulating layer 120 and the lower insulating layer 150 may be made of prepreg that is resin in which reinforcement materials, such as glass fiber, inorganic filler, and the like, are impregnated into the epoxy resin or the polyimide. Further, the upper insulating layer 120 and the lower insulating layer 150 may be made of a photocurable resin. The material of the lower insulating layer 150 and the upper insulating layer 120 is not limited thereto, and therefore the lower insulating layer 150 and the upper insulating layer 120 may be made of any of the inter-layer insulating materials generally used.

The upper circuit layer 130 and the lower circuit layer 160 may be made of conductive materials. For example, the upper circuit layer 130 and the lower circuit layer 160 may be made of conductive metals, such as gold, silver, zinc, palladium, ruthenium, nickel, copper, and the like. The material of the upper circuit layer 130 and the lower circuit layer 160 is not limited thereto, and therefore, the upper circuit layer 130 and the lower circuit layer 160 may be made of any of the conductive materials generally used at the time of forming a circuit.

As illustrated in FIG. 1, the first upper insulating layer 121, the second upper insulating layer 122, and the third upper insulating layer 123 may have different thicknesses. Further, the first upper circuit layer 131, the second upper circuit layer 132, and the third upper circuit layer 133 may have different thicknesses.

Further, the first lower insulating layer 151 and the second lower insulating layer 152 may have the same thickness. Further, the first lower circuit layer 161 and the second lower circuit layer 162 may have the same thickness.

According to the preferred embodiment of the present invention, a total thickness of the upper insulating layer 120 may be formed to be thicker than that of the lower insulating layer 150. Herein, the total thickness of the upper insulating layer 120 may be a sum of the thicknesses of the first upper insulating layer 121 to the third upper insulating layer 123, respectively. Further, a total thickness of the lower insulating layer 150 may be a sum of the thicknesses of the first lower insulating layer 151 and the second lower insulating layer 152, respectively.

Further, according to the preferred embodiment of the present invention, a total thickness of the upper circuit layer 130 may be formed to be thicker than that of the lower circuit layer 160. Herein, the total thickness of the upper circuit layer 130 may be a sum of the thicknesses of the first upper circuit layer 131 to the third upper circuit layer 133, respectively. Further, the total thickness of the lower circuit layer 160 may be a sum of the thicknesses of the first lower circuit layer 161 and the second lower circuit layer 162, respectively.

A ratio of the thickness of the upper build-up layer 140 and the thickness of the lower build-up layer 170 of the so formed printed circuit board 100 may be 20% or less. According to the preferred embodiment of the present invention, the upper build-up layer 140 is formed to be thicker than the lower build-up layer 170 and the thickness ratio thereof may be 20%.

For example, the upper insulating layer 120 is formed to be thicker than the lower insulating layer 150 and the thickness ratio thereof may be 20% or less. This may be represented by the following Equation 1.

1≦(I_{Tn}+I_{Tn-1}+I_{Tn-2}+ . . . +I_{Tn-(n-1)})/(I_{Bn}+I_{Bn-1}+I_{Bn-2}+ . . . +I_{Bn-(n-1)})≦1.2 [Equation 1]

In the above Equation 1, I_{Tn} represents the thickness of the insulating layer formed on an n layer among the upper insulating layers. Further, I_{Bn} represents the thickness of the insulating layer formed on an n layer among the lower insulating layers. Herein, n is a natural number of 1 or more.

For example, the upper circuit layer 130 is formed to be thicker than the lower circuit layer 160 and the thickness ratio thereof may be 20% or less. This may be represented by the following Equation 2.

1≦(M_{Tn}+M_{Tn-1}+M_{Tn-2}+ . . . +M_{Tn-(n-1)})/(M_{Bn}+M_{Bn}+M_{Bn-2}+ . . . +M_{Bn-(n-1)})≦1.2 [Equation 2]

In the above Equation 2, M_{Tn} represents the thickness of the circuit layer formed on an n layer among the upper circuit layers. Further, M_{Tn} represents the thickness of the circuit layer formed on an n layer among the lower circuit layers. Herein, n is a natural number of 1 or more.

FIG. 2 is an exemplified diagram illustrating a printed circuit board according to another preferred embodiment of the present invention.

Referring to FIG. 2, a printed circuit board 200 may include a base board 210, an upper build-up layer 240, and a lower build-up layer 270.

The printed circuit board 200 according to the preferred embodiment of the present invention may be an asymmetrical board in which thicknesses of an upper build-up layer 240 and a lower build-up layer 270 formed on one side and the other side thereof are different from each other.

The base board 210 may be an insulating board, a printed circuit board, a ceramic board, and a metal board having an anodizing layer. Generally, the insulating board may be a composite polymer resin used as an inter-layer insulating material. The insulating board may be made of at least one of prepreg, Ajinomoto build-up film (ABF), FR-4, and bismaleimide triazine (BT).

In the printed circuit board an internal circuit of at least one layer may be formed on an insulating layer. In this case, the insulating layer may be a composite polymer resin generally used as an inter-layer insulating material. The internal circuit may be made of conductive materials generally used at the time of forming a circuit.

The ceramic board may be made of metal-based nitride and a ceramic material. The ceramic board may include aluminum nitride (AlN) or silicon nitride (SiN) that is the metal-based nitride. The ceramic board may include aluminum oxide (Al₂O₃) or beryllium oxide (BeO) that is the ceramic material. However, the material of the ceramic board is not particularly limited thereto.

The metal board may be made of metal materials that may be easily available at relatively low cost and aluminum (Al) or aluminum alloy having excellent heat transfer characteristics. Further, the anodizing layer may be formed by dipping the metal board made of aluminum or aluminum alloy into electrolytes, such as boric acid, phosphoric acid, sulfuric acid, chromic acid, and the like, and then applying an anode to the metal board and a cathode to the electrolyte. The so formed anodizing layer may be an aluminum anodizing layer (Al₂O₃). The anodizing layer may have insulation and high heat transfer characteristics.

The upper build-up layer 240 is formed on one side of the base board 210. The upper build-up layer 240 may include an upper insulating layer 220 having at least one layer. Further, the upper build-up layer 240 may include an upper circuit layer 230 having at least one layer. According to the preferred embodiment of the present invention, the upper build-up layer 240 may include the upper insulating layer 220 having two layers. For example, the upper insulating layer 220 may include a first upper insulating layer 221 and a second upper insulating layer 222. Further, the upper build-up layer 240 may include the upper circuit layer 230 having two layers. For example, the upper circuit layer 230 may include a first upper circuit layer 231 and a second upper circuit layer 232.

The lower build-up layer 270 is formed on the other side of the base board 210. The lower build-up layer 270 may be formed to be thicker than the upper build-up layer 240. The lower build-up layer 270 may include a lower insulating layer 250 having at least one layer. Further, the lower build-up layer 270 may include a lower circuit layer 260 having at least one layer. According to the preferred embodiment of the present invention, the lower build-up layer 270 may include the lower insulating layer 250 having three layers. For example, the lower insulating layer 250 may include a first lower insulating layer 251, a second lower insulating layer 252, and a third lower insulating layer 253. Further, the lower build-up layer 270 may include the lower circuit layer 260 having three layers. The lower circuit layer 260 may include a first lower circuit layer 261, a second lower circuit layer 262, and a third circuit layer 263.

The upper insulating layer 220 and the lower insulating layer 250 may be a composite polymer resin used as an inter-layer insulating material. For example, the upper insulating layer 220 and the lower insulating layer 250 may be made of a thermosetting resin, such as epoxy resin, and the like. The epoxy resin may be Ajinomoto build up film (ABF), FR-4, bismaleimide triazine (BT), and the like. Further, the upper insulating layer 220 and the lower insulating layer 250 may be made of a thermoplastic resin. The thermoplastic resin may be polyimide. Further, the upper insulating layer 220 and the lower insulating layer 250 may be made of prepreg that is a resin in which reinforcement materials, such as glass fiber, inorganic filler, and the like, are impregnated into the epoxy resin or the polyimide. Further, the upper insulating layer 220 and the lower insulating layer 250 may be made of a photocurable resin. The material of the lower insulating layer 250 and the upper insulating layer 220 is not limited thereto, and therefore the lower insulating layer 250 and the upper insulating layer 220 may be made of any of the inter-layer insulating materials generally used.

The upper circuit layer 230 and the lower circuit layer 260 may be made of conductive materials. For example, the upper circuit layer 230 and the lower circuit layer 260 may be made of conductive metals, such as gold, silver, zinc, palladium, ruthenium, nickel, copper, and the like. The material of the upper circuit layer 230 and the lower circuit layer 260 is not limited thereto, and therefore, the upper circuit layer 230 and the lower circuit layer 260 may be made of any of conductive materials generally used at the time of forming a circuit.

As illustrated in FIG. 2, the first upper insulating layer 221 and the second upper insulating layer 222 may have the same thickness. Further, the first upper circuit layer 231 and the second upper circuit layer 232 may have the same thickness. Further, the first lower insulating layer 251, the second lower insulating layer 252, and the third lower insulating layer 253 may have different thicknesses. Further, the first lower circuit layer 261, the second lower circuit layer 262, and the third lower circuit layer 263 may have different thicknesses.

According to the preferred embodiment of the present invention, a total thickness of the upper insulating layer 220 may be formed to be thinner than that of the lower insulating layer 250. Herein, the total thickness of the upper insulating layer 220 may be a sum of the thicknesses of the first upper insulating layer 221 and the second upper insulating layer 222, respectively. Further, a total thickness of the lower insulating layer 250 may be a sum of the thicknesses of the first lower insulating layer 251 to the third lower insulating layer 253, respectively.

Further, according to the preferred embodiment of the present invention, a total thickness of the upper circuit layer 230 may be formed to be thinner than that of the lower circuit layer 260. Herein, the total thickness of the upper circuit layer 230 may be a sum of the thicknesses of the first upper circuit layer 231 and the second upper circuit layer 232, respectively. Further, the total thickness of the lower circuit layer 260 may be a sum of the thicknesses of the first lower circuit layer 261 to the third lower circuit layer 263, respectively.

A ratio of the thickness of the upper build-up layer 240 and the thickness of the lower build-up layer 270 of the so formed printed circuit board 200 may be 20% or less. According to the preferred embodiment of the present invention, the upper build-up layer 240 is formed to be thinner than the lower build-up layer 270 and the thickness ratio thereof may be 20%.

For example, the upper insulating layer 220 is formed to be thinner than the lower insulating layer 250 and the thickness ratio thereof may be 20% or less. This may be represented by the following Equation 3.

0.8≦(I_{Tn}+I_{Tn-1}+I_{Tn-2}+ . . . +I_{Tn-(n-1)})/(I_{Bn}+I_{Bn-1}+I_{Bn-2}+ . . . +I_{Bn-(n-1)})<1 [Equation 3]

In the above Equation 3, I_{Tn} represents the thickness of the insulating layer formed on an n layer among the upper insulating layers. Further, I_{Bn} represents the thickness of the insulating layer formed on an n layer among the lower insulating layers. Herein, n is a natural number of 1 or more.

Further, the upper circuit layer 230 is formed to be thinner than the lower circuit layer 260 and the thickness ratio thereof may be 20% or less. This may be represented by the following Equation 4.

0.8≦(M_{Tn}+_{MTn-1}+M_{Tn-2}+ . . . +M_{Tn-(n-1)})/(M_{Bn}+M_{Bn-1}+M_{Bn-2}+ . . . +M_{Bn-(n-1)})≦1 [Equation 4]

In the above Equation 4, MTn represents the thickness of the circuit layer formed on an n layer among the upper circuit layers. Further, M_{Bn} represents the thickness of the circuit layer formed on an n layer among the lower circuit layers. Herein, n is a natural number of 1 or more.

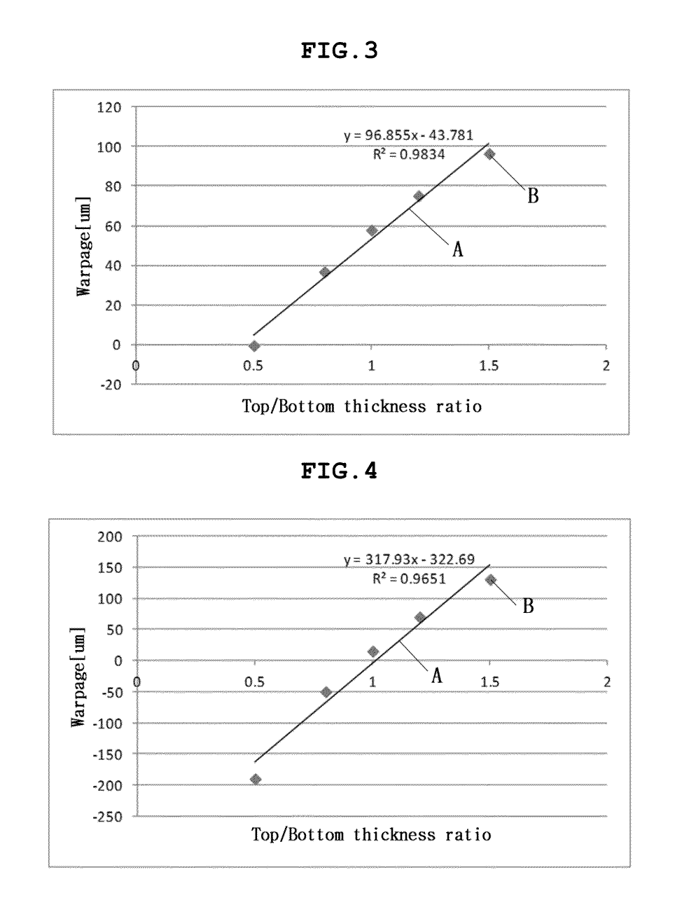

FIG. 3 is an exemplified diagram illustrating an analysis result of warpage according to the preferred embodiment of the present invention.

Referring to FIG. 3, the printed circuit board includes the upper build-up layer and the lower build-up layer. The upper build-up layer may include the upper insulating layer having three layers and the upper circuit layer having three layers. Further, the lower build-up layer may include the lower insulating layer having two layers and the lower circuit layer having two layers. The thicknesses of the insulating layer and the circuit layer of each layer are as the following [Table 1].

TABLE 1

| | Ratio Of Thickness of | | | | |
|---|---|---|---|---|---|
| | Upper Build-up Layer and | | | | |
| | Thickness of Lower Build-up Layer | | | | |
| Layer Number | 0.5 | 0.8 | 1.0 | 1.2 | 1.5 |
| Third Upper Insulating Layer | 15 | 15 | 15 | 15 | 15 |
| Third Upper Circuit Layer | 5 | 4 | 5 | 10 | 15 |
| Second Upper Insulating | 32 | 32 | 32 | 32 | 32 |
| Layer | | | | | |
| Second Upper Circuit Layer | 5 | 5 | 10 | 11 | 15 |
| First Upper Insulating Layer | 32 | 32 | 32 | 32 | 32 |
| First Upper Circuit Layer | 5 | 15 | 15 | 15 | 15 |
| Base Board | 220 | 220 | 220 | 220 | 220 |
| First Lower Circuit Layer | 15 | 15 | 15 | 15 | 15 |
| First Lower Insulating Layer | 32 | 32 | 32 | 32 | 32 |
| Second Lower Circuit Layer | 15 | 15 | 15 | 15 | 15 |
| Second Lower Insulating | 15 | 15 | 15 | 15 | 15 |
| Layer | | | | | |

FIG. 3 illustrates an analysis result of the warpage of the printed circuit board having the thickness shown in the above [Table 1].

Referring to FIG. 3, warpage A of the printed circuit board according to the related art of which the upper and lower thicknesses are the same may be compared with warpage B of the printed circuit board according to the preferred embodiment of the present invention. It may be confirmed that the printed circuit board is less warped than the printed circuit board according to the related art, in the case in which the thickness ratio of the upper build-up layer and the lower build-up layer is 0.8 to 1.2.

FIG. 4 is an exemplified diagram illustrating an analysis result of warpage according to another preferred embodiment of the present invention.

FIG. 4 illustrates the analysis result of warpage after the thicknesses of the circuit layer and the insulating layer of each layer are differently changed from FIG. 3. The thicknesses of the insulating layer and the circuit layer of each layer configuring the printed circuit board according to the preferred embodiment of the present invention are as the following [Table 2].

TABLE 2

| | Ratio Of Thickness of | | | | |
|---|---|---|---|---|---|
| | Upper Build-up Layer and | | | | |
| | Thickness of Lower Build-up Layer | | | | |
| Layer Number | 0.5 | 0.8 | 1.0 | 1.2 | 1.5 |
| Third Upper Insulating Layer | 5 | 5 | 5 | 5 | 5 |
| Third Upper Circuit Layer | 5 | 4 | 5 | 10 | 15 |
| Second Upper Insulating | 5 | 5 | 5 | 5 | 5 |
| Layer | | | | | |
| Second Upper Circuit Layer | 5 | 10 | 10 | 11 | 15 |
| First Upper Insulating Layer | 5 | 6 | 5 | 5 | 5 |
| First Upper Circuit Layer | 5 | 10 | 15 | 15 | 15 |
| Base Board | 220 | 220 | 220 | 220 | 220 |
| First Lower Circuit Layer | 15 | 15 | 15 | 15 | 15 |
| First Lower Insulating Layer | 5 | 5 | 5 | 5 | 5 |
| Second Lower Circuit Layer | 15 | 15 | 15 | 15 | 15 |
| Second Lower Insulating | 5 | 5 | 5 | 5 | 5 |
| Layer | | | | | |

FIG. 4 illustrates an analysis result of warpage of the printed circuit board having the thickness shown in the above [Table 2].

Referring to FIG. 4, warpage A of the printed circuit board according to the related art of which the upper and lower thicknesses are the same may be compared with warpage B of the printed circuit board according to the preferred embodiment of the present invention. It may be confirmed that the printed circuit board is less warped than the printed circuit board according to the related art, in the case in which the thickness ratio of the upper build-up layer and the lower build-up layer is 0.8 to 1.2.

The warpage of the printed circuit board according to the preferred embodiment of the present invention may be prevented by taking a structure in which the mutual thickness ratio of the upper build-up layer and the lower build-up layer is 0.8 to 1.2. That is, the printed circuit board according to the preferred embodiment of the present invention may be formed so that the thicknesses of the upper build-up layer and the lower build-up layer are 20% or so. In this case, the thickness ratio of the upper build-up layer and the lower build-up layer may be controlled to the thicknesses of the insulating layers or the circuit layers included in each build-up layer. Alternatively, the thickness ratio of the upper build-up layer and the lower build-up layer may be controlled by simultaneously controlling the thicknesses of the insulating layer and the circuit layer.

According to the preferred embodiments of the present invention, it is possible to reduce warpage of the board by controlling the thicknesses of the upper and lower build-up layers.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
a base board;
an upper build-up layer which is formed on the base board and includes an upper insulating layer and an upper circuit layer of at least one layer; and
a lower build-up layer which is formed beneath the base board, has a different thickness from the upper build-up layer, and includes a lower insulating layer and a lower circuit layer of at least one layer.

2. The printed circuit board as set forth in claim 1, wherein the thickness of the upper build-up layer is thicker than that of the lower build-up layer.

3. The printed circuit board as set forth in claim 1, wherein the thickness of the upper build-up layer is thinner than that of the lower build-up layer.

4. The printed circuit board as set forth in claim 1, wherein a total thickness of the upper insulating layer is thicker than that of the lower insulating layer.

5. The printed circuit board as set forth in claim 1, wherein a total thickness of the upper insulating layer is thinner than that of the lower insulating layer.

6. The printed circuit board as set forth in claim 1, wherein a total thickness of the upper circuit layer is thicker than that of the lower circuit layer.

7. The printed circuit board as set forth in claim 1, wherein a total thickness of the upper circuit layer is thinner than that of the lower circuit layer.

8. The printed circuit board as set forth in claim 1, wherein a layer number of the upper insulating layer and the upper circuit layer is larger than that of the lower insulating layer and the lower circuit layer.

9. The printed circuit board as set forth in claim 1, wherein a layer number of the upper insulating layer and the upper circuit layer is smaller than that of the lower insulating layer and the lower circuit layer.

10. The printed circuit board as set forth in claim 1, wherein a ratio of the thickness of the upper build-up layer and the thickness of the lower build-up layer is 20% or less.

11. The printed circuit board as set forth in claim 10, wherein a ratio of a total thickness of the upper circuit layer and a total thickness of the lower circuit layer are 20% or less.

12. The printed circuit board as set forth in claim 10, wherein a ratio of a total thickness of the upper circuit layer and a total thickness of the lower circuit layer are 20% or less.
